(19) United States
(12) Patent Application Publication
(10) Pub. No.: US 2019/0179528 A1
(43) Pub. Date: Jun. 13, 2019

(54) INFORMATION PROCESSING METHOD, INFORMATION PROCESSING TERMINAL, AND NON-TRANSITORY COMPUTER-READABLE RECORDING MEDIUM STORING PROGRAM FOR INFORMATION PROCESSING

(71) Applicant: LINE Corporation, Tokyo (JP)

(72) Inventor: Nobuo SAITO, Fukuoka (JP)

(73) Assignee: LINE Corporation, Tokyo (JP)

(21) Appl. No.: 16/266,502

(22) Filed: Feb. 4, 2019

Related U.S. Application Data
(63) Continuation of application No. PCT/JP2047/024439, filed on Jul. 4, 2017.

(30) Foreign Application Priority Data
Aug. 4, 2016 (JP) 2016-154057

(51) Int. Cl. G06F 3/0488; G06F 3/044; H03K 17/96; G06F 3/041

(52) U.S. Cl. CPC G06F 3/04883; G06F 3/0414; H03K 17/962; G06F 3/044

(57) ABSTRACT

Manipulation methods, non-transitory computer-readable recording media storing a program that, when executed by a processor, causes the processor to execute the manipulation method, and information processing terminals capable of invalidating a manipulation unintended by a user in a user manipulation with respect to a touch panel may be provided. An information processing method may include detecting a manipulation with respect to a touch panel, executing process content corresponding to the detected manipulation, displaying display-content corresponding to the executed process content, determining an invalidation time, which is a time to invalidate the process content corresponding to the manipulation, in response to an elapsed time after the manipulation on the touch panel has stopped exceeding a threshold time, and causing not to execute the executed process content based on a determination that the detected manipulation is within the invalidation time may be provided.

### CROSS-REFERENCE TO RELATED APPLICATIONS

This U.S. non-provisional application is a continuation application of, and claims the benefit of priority under 35 U.S.C. § 365(c) from, International Application PCT/JP2017/024439 filed on Jul. 4, 2017, and designated the U.S., which is based upon and claims the benefit of priority of Japanese Patent Application No. 2016-154057, filed on Aug. 4, 2016, the entire contents of each of which are incorporated herein by reference in their entirety.

### BACKGROUND

### Technical Field

The present inventive concepts relate to information processing methods, information processing terminals, and/or non-transitory computer-readable recording media storing a program for information processing.

### Background Art

In recent years, terminals including a touch panel in a display have become widespread. A user can execute a function associated with an object (e.g., an icon) on the touch panel by separating a finger after causing the finger to come in contact with the object. Such a terminal detects a position on the touch panel at which the user has been separated from the touch panel, and executes a function associated with the object at the detected position.

However, when the finger of the user is larger than the object (e.g., the icon), chances are that there is a difference between a position at which the user intends to separate the finger from the touch panel and a position detected by the terminal when the finger is separated from the touch panel. Accordingly, a function intended by the user may not be precisely executed, or an erroneous manipulation may be caused.

According to an conventional technique, a function assigned to a specific area on a touch panel may be temporarily invalidated when the area is continuously touched for a predetermined time in a case in which a specific mode is set in a user terminal including the touch panel such that the function associated with the area is not activated even when touch-up is performed. In such cases, it is possible to suppress function activation when a user unintentionally touches the touch panel. Thus, an erroneous manipulation may be reduced. This technique temporarily invalidates the function assigned to the specific area when the area is continuously touched for a predetermined time in the specific mode. Thus, invalidation of the function is limited to the specific mode and the specific area. Accordingly, an erroneous manipulation of the user in modes and areas other than the specific mode and the specific area may not be prevented.

According to another conventional technique, Graphical User Interface (GUI) components, such as buttons displayed on a display surface may be classified into a plurality of groups in a display device (e.g., a touch panel), and a manipulation input to a specific GUI component applied to a group (which is different from a specific group including the specific GUI component), with which the finger comes in contact when it is detected that a finger comes in contact with the display surface, may be invalidated. In such case, it is possible to prevent an operation according to a manipulation input, which is unintended by a user, from being executed. Further, invalidation of the manipulation input to the specific GUI component by this technique is limited to a group other than the same group including the specific GUI component. Thus, an erroneous manipulation of the user to GUI components other than the specific GUI components in the same specific group may not be prevented.

According to still another conventional technique, whether an operation is a sliding operation or a selection operation on the basis of a movement distance and a movement time of a release operation from a touch operation received by a touch panel may be determined, and an operation from the touch operation to the release operation may be ignored when it is determined that a manipulation is the selection manipulation. In such cases, whether or not a manipulation is a manipulation related to selection may be determined on the basis of two factors including a movement distance and a pressing time between a previous touch operation and the release operation. Thus, misjudgment of a manipulation related to a sliding operation of a user and a manipulation related to a selection operation can be suppressed. According to this technique, the operation from the touch operation to the release operation is ignored when it is determined that the manipulation is the selection manipulation. In other words, the release operation is ignored limitedly in the case of the selection manipulation. Thus, an erroneous manipulation of the user may not be prevented in cases other than the selection manipulation.

The present inventive concepts have been made in view of the above problem and some example embodiments of the present inventive concepts relate to manipulation methods, information processing terminals capable of invalidating a manipulation unintended by a user in a user manipulation with respect to a touch panel, and/or non-transitory computer-readable recording media storing instructions program for information processing.

### SUMMARY

According to an example embodiment, an information processing method in an information processing terminal may include detecting a manipulation with respect to a touch panel by a manipulation body that performs a manipulation input, executing process content corresponding to the detected manipulation, displaying display-content corresponding to the executed process content, determining an invalidation time, the invalidation time being a time to invalidate the process content corresponding to the manipulation by the manipulation body, in response to an elapsed time after a movement of the manipulation body on the touch panel has stopped exceeding a threshold time, and causing not to execute the executed process content based on a determination that the detected manipulation is within the invalidation time.

In some example embodiments, the detecting may include detecting a separation manipulation of separating the manipulation body from the touch panel within the invalidation time, and the executing may include executing the process content corresponding to the separating manipulation based on a position at which the movement of the manipulation body is separated from the touch panel.

In some example embodiments, the executing may include executing the process content corresponding to the separating manipulation with respect to an object displayed at a position at which the manipulation body is separated from the touch panel.

In some example embodiments, the determining may include determining a length of the invalidation time based on an elapsed time after the movement of the manipulation body stops.

In some example embodiments, the information processing method may further include storing information on the process content corresponding to the detected manipulation based on a detection result that the detected manipulation with respect to the touch panel of the manipulation body is within the invalidation time.

In some example embodiments, the detecting may further include detecting a restarting movement of the manipulation body on the touch panel after the movement has stopped, and the executing may include executing the process content corresponding to the detected manipulation, which is associated with the restarting movement, and the stored information in response to the restarting movement exceeding the invalidation time.

In some example embodiments, the displaying may include displaying the display-content corresponding to the executed process content at the invalidation time in response to the restarting movement exceeding the invalidation time.

In some example embodiments, the determining may further include determining an invalidation range, the invalidation range being a range in which the process content corresponding to the detected manipulation by the manipulation body is invalidated on the touch panel, in response to the elapsed time after the movement of the manipulation body on the touch panel has stopped exceeding both the threshold time and the invalidation time, and the causing may include causing not to execute the executed process content corresponding to the manipulation of the manipulation body that is within both the invalidation range and the invalidation time.

In some example embodiments, the determining may further include determining the invalidation range based on a function.

In some example embodiments, the determining may further include determining the invalidation time based on a function.

According to an example embodiment, a non-transitory computer-readable recording medium storing a program that, when executed by a processor, causes the processor to execute an information processing method, which includes detecting a manipulation with respect to a touch panel by a manipulation body that performs a manipulation input, executing process content corresponding to the detected manipulation, displaying display-content corresponding to the executed process content, determining an invalidation time, is the invalidation time being a time to invalidate the process content corresponding to the manipulation by the manipulation body based on an elapsed time after a movement of the manipulation body on the touch panel stops exceeds a threshold time, and causing not to execute the process content based on a determination that the detected manipulation is within the invalidation time.

According to an example embodiment, an information processing terminal may include a storage configured to store computer-readable instructions. and one or more processors configured to execute the computer-readable instructions such that the one or more processors are configured to detect a manipulation with respect to a touch panel by a manipulation body that performs a manipulation input, execute process content corresponding to the detected manipulation, display display-content corresponding to the executed process content, determine an invalidation time, the invalidation time being a time to invalidate the process content corresponding to the manipulation of the manipulation body based on an elapsed time after a movement by the manipulation body on the touch panel stops exceeds a threshold time, and cause not to execute the process content based on a determination that the detected manipulation is within the determined invalidation time.

According to the present disclosure, it is possible to provide an information processing terminal capable of invalidating a manipulation not intended by the user in the user manipulation with respect to the touch panel.

### BRIEF DESCRIPTION OF THE DRAWINGS

FIG. 1 is a diagram illustrating a configuration example of a system according to an example embodiment of the present inventive concepts.

FIG. 2 is a diagram illustrating a configuration example of a terminal according to an example embodiment of the present inventive concepts.

FIG. 3 is a schematic diagram illustrating a cross section of a pressure-sensitive touch panel.

FIG. 4A is a schematic diagram illustrating a cross section of a surface type capacitive touch panel.

FIG. 4B is a schematic diagram illustrating a cross section of a projection type capacitive touch panel

FIGS. 5A, 5B, and 5C are diagrams illustrating display-content that is displayed on a touch panel of the terminal according to an example embodiment.

FIG. 6 is a flowchart showing an example of operations of the terminal according to an example embodiment.

FIGS. 7A, 7B, and 7C are diagrams illustrating display-content displayed on a touch panel of a terminal according to an example embodiment.

FIG. 8 is a flowchart showing some example operations of a terminal according to an example embodiment.

FIGS. 9A, 9B, and 9C are diagrams showing display-content displayed on a touch panel of the terminal according to an example embodiment.

FIG. 10 is a flowchart showing an example of operations of a terminal according to an example embodiment.

### DETAILED DESCRIPTION

The present inventive concepts have been made in view of the problems described in the BACKGROUND section, and some example embodiments of the present inventive concepts relate to manipulation methods, information processing terminals capable of invalidating a manipulation unintended by a user in a user manipulation with respect to a touch panel, and/or non-transitory computer-readable recording media storing program for information processing.

<Compliance with Communication Secrets>

It should be noted that when the inventive concepts described in this disclosure is implemented, the inventive concepts may be implemented after legal matters relating to secrecy of confidentiality of communications are complied with.

Some example embodiments of the present inventive concepts will be described with reference to the drawings.

<System Configuration>

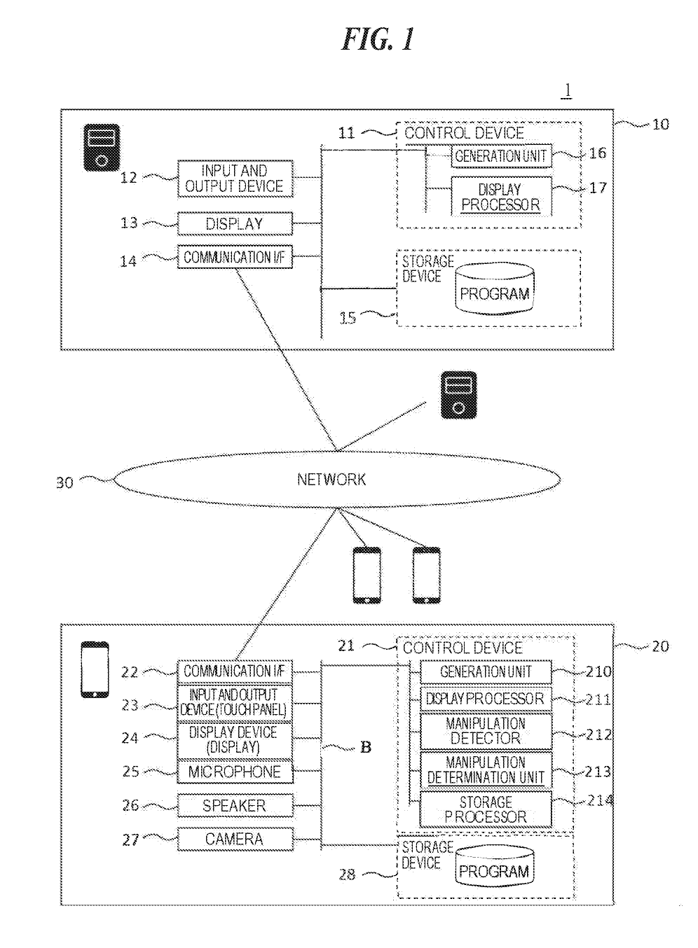

FIG. 1 is a diagram illustrating a configuration of a communication system according to an embodiment of the present disclosure. As illustrated in FIG. 1, in a communication system 1, a server 10 and terminal 20 (20A, 20B, and 20C) may be connected via a network 30. The server 10 may provide a service for realizing transmission and reception of messages to and from the terminals 20 owned by a user, for example, to and from the terminal 20 via the network 30. It should be noted that the number of terminals 20 connected to the network 30 is not limited.

The network 30 may play a role of connecting one or more terminals 20 to one or more servers 10. That is, the network 30 may mean a communication network that provides a connection path so that the terminal 20 can transmit or receive data after connecting to the server 10.

For example, one or more portions of the network 30 may be a wired network or a wireless network. The network 30 may include an ad hoc network, an intranet, an extranet, a virtual private network (VPN), a local area network (LAN), a wireless LAN (WLAN), a wide area network (WAN), a wireless WAN (WWAN), a metropolitan area network (MAN), a portion of the Internet, a portion of a public switched telephone network (PSTN), a mobile phone network, integrated service digital networks (ISDNs), wireless LANs, long term evolution (LTE) code division multiple access (CDMA), Bluetooth (registered trademark), satellite communication, or a combination of two or more of these. However, in the present disclosure, the network 30 is not limited thereto. Further, the network 30 may also include one or a plurality of networks 30.

The terminal 20 (20A, 20B, and 20C) may be any terminal as long as the information processing terminal can realize functions described in the example embodiments below. The terminal 20 is, for example, a smart phone. An example of the terminal 20 may include a mobile phone (for example, a feature phone), a computer (for example, a desktop, laptop, or tablet computer), a media computer platform (for example, a cable, a satellite set-top box, or a digital video recorder), a handheld computing device (for example, a personal digital assistant (PDA) or an e-mail client), a wearable terminal (for example, a glasses type device or a clock type device), another type of computer, or a communication platform. However, in the present inventive concepts, the terminal 20 is not limited thereto. Further, the terminal 20 may be indicated as an information processing device 20.

Configurations of the terminals 20A, 20B, and 20C may be basically the same. The terminals 20A, 20B, and 20C are described as terminals 20. Hereinafter, the terminal 20A is described as a subject terminal 20A, the terminal 20B is described as another terminal 20B, and the terminal 20C is described as the other terminal 20C, as desired.

The server 10 includes a function of providing a service (e.g., a desired or predetermined service) to the terminal 20. The server 10 may be any type of information processing device as long as the device can realize functions described in the example embodiments below. The server 10 may be, for example, a server device. Another example of server 10 may include a computer (e.g., a desktop, laptop, or tablet computer), a media computer platform (e.g., a cable, a satellite set-top box, or a digital video recorder), a handheld computing device (e.g., a PDA or an e-mail client), or another type of computer, or a communication platform. However, in the present inventive concepts, the server 10 is not limited thereto. Further, the server 10 may be indicated as an information processing device.

<Hardware (HW) Configuration>

A HW configuration of each device included in the communication system 1 will be described with reference to FIG. 1.

(1) HW configuration of Terminal

The terminal 20 may include a control device (CPU: Central Processing Unit) 11, a storage device 28, a communication interface (I/F) 22, an input and output device 23, a display device 24, a microphone 25, a speaker 26, and a camera 27. Each component of the HW of the terminal 20 may be connected to other components via a bus B, for example.

The communication I/F 22 may perform transmission or reception of various types of data via the network 30. The communication may be executed by a cable or wirelessly, and any communication protocol may be used as long as mutual communication can be executed.

The input and output device 23 includes a device that inputs various manipulations to the terminal 20 and a device that outputs a processing result of the terminal 20. The input and output device 23 may be an integral device of an input device and an output device or the input and output device 23 may include an input device and an output device separately.

The input device may be realized by any one or combination of all types of devices that can receive an input from the user and transmit information related to the input to the control device 21. For example, the input device may be realized by a touch panel, detect a contact of an indication tool such as a finger of the user or a stylus and a contact position, and transfer coordinates of the contact position to the control device 21. On the other hand, the input device may be realized by an input and output device 23 other than the touch panel. Examples of the input device include a keyboard, a pointing device (e.g., a mouse), a camera (manipulation input via a moving image), and a microphone (manipulation input by voice). However, in the present inventive concepts, the input device is not limited thereto.

The output device may be realized by any one or combination of all types of devices capable of outputting a processing result of the control device 21. For example, the output device may be realized by a touch panel. On the other hand, the output device may be realized by an output device other than the touch panel. Examples of the output device include a speaker (sound output), a lens (e.g., 3D (three dimensional) output or hologram output), and a printer. However, in the present inventive concepts, the output device is not limited thereto.

The display device 24 may be realized by any one or combination of all types of devices that can perform a display according to display data written in a frame buffer. The display device 24 may be realized by a monitor (e.g., a liquid crystal display or an organic electroluminescence display (OELD)). The display device 24 may be a head mounted display (HMD). Further, the display device 24 may be realized by a device capable of displaying an image, text information, or the like in projection mapping, hologram, air (which may be a vacuum), or the like. It should be noted that the display device 24 may be capable of displaying display data in 3D. However, in the present inventive concepts, the display device 24 is not limited thereto.

When the input and output device 23 is a touch panel, the input and output device 23 and the display device 24 may be disposed to face each other with substantially the same size and shape.

The control device 21 may include a circuit physically structured to execute functions realized by code or instructions included in a program, and may be realized by, for example, a built-in-hardware data processing device.

The control device 21 may be a central processing unit (CPU. In addition, the control device 21 may be a microprocessor, a processor core, a multiprocessor, an application-specific integrated circuit (ASIC), or a field programmable gate array (FPGA). However, in the present inventive concepts, the control device 21 is not limited thereto.

The storage device 28 may have a function of storing various programs or various types of data required for an operation of the terminal 20. The storage device 28 may be realized by various storage media (e.g., a hard disk drive (HDD), a solid state drive (SSD), a flash memory, a random access memory (RAM), or a read only memory (ROM)). However, in the present inventive concepts, the storage device 28 is not limited thereto.

The terminal 20 may store a program in the storage device 28 and execute this program. Accordingly, the control device 21 may execute various functions (or operations) of each unit included in the control device 21. That is, the program stored in the storage device 28 may cause the control device 21 of the terminal 20 to execute the respective functions.

The microphone 25 may be used for input of audio data. The speaker 26 may be used for output of audio data. The camera 27 may be used for acquisition of moving image data.

(2) HW Configuration of Server

The server 10 may include a control device (CPU) 11, a storage device 15, a communication interface (I/F) 14, an input and output device 12, and a display 13.

The control device 11 may include a circuit physically structured to execute a function realized by a code or instructions included in the program, and may be realized by, for example, a data processing device built in hardware. The control device 11 may include a generation unit (or generation circuit) 16, and a display processor (or display processing circuit) 17.

The control device 11 may be, for example, a central processing unit (CPU). The control device 11 may be a microprocessor, a processor core, a multiprocessor, an ASIC, or an FPGA. However, in the present inventive concepts, the control device 11 is not limited thereto.

The storage device 15 may have a function of storing various programs or various types of data desired for the server 10 to operate. The storage device 15 may be realized by various storage media such as an HDD, an SSD, or a flash memory. However, in the present inventive concepts, the storage device 15 is not limited thereto.

The communication I/F 14 may perform transmission or reception of various types of data via the network 30. The communication may be executed by a cable or wirelessly, and any communication protocol may be used as long as mutual communication can be executed.

The input and output device 12 may be realized by a device that inputs various manipulations to the server 10. The input and output device 12 may be realized by any one or combination of all types of devices that can receive an input from the user and transfer information related to the input to the control device 11. The input and output device 12 may be realized by a keyboard, or a pointing device (e.g., a mouse). It should be noted that the input and output device 12 may include, for example, a touch panel, a camera (manipulation input via a moving image), or a microphone (manipulation input by voice). However, in the present inventive concepts, the input and output device 12 is not limited thereto.

The display 13 may be realized with a monitor (e.g., a liquid crystal display or an organic electroluminescence display (OELD)). In some example embodiments, the display 13 may be a head mounted display (HDM). It should be noted that these displays 13 may be capable of displaying display data in 3D. However, in the present inventive concepts, the display 13 is not limited thereto.

In the example embodiments described below, the control device 21 of the terminal 20 and/or the control device 11 of the server 10 executing the program will be implemented by a CPU.

It should be noted that in the terminal 20 and/or the server 10, the control device 11 may realize each process using not only a CPU but also a logic circuit (hardware) formed in an integrated circuit (an integrated circuit (IC) chip or a large scale integration (LSI)) or a dedicated circuit. Further, these circuits may be realized by one or a plurality of integrated circuits, and the plurality of processes described in the above example embodiment may be realized by one integrated circuit. Further, the LSI may also be referred to as VLSI, Super LSI, Ultra LSI or the like according to a degree of integration.

Further, the program (software program/computer program) of each example embodiment of the present inventive concepts may be provided in a state stored in a computer-readable storage medium. The storage medium can store the program in a “non-transient tangible medium”.

A storage medium may include one or a plurality of semiconductor-based integrated circuits or another integrated circuit (IC) (for example, a field programmable gate array (FPGA) or an application specific integrated circuit (ASIC)), a hard disk drive (HDD), a hybrid hard drive (HHD), an optical disk, an optical disk drive (ODD), a magneto-optical disk, a magneto-optical drive, a floppy diskette, a floppy disk drive (FDD), a magnetic tape, a solid-state drive (SSD), a RAM drive, a secure digital card or drive, any other suitable storage medium, or any suitable combination of two or more of these, if appropriate. The storage medium may be volatile, non-volatile, or a combination of volatile and non-volatile, if appropriate. It should be noted that the storage medium is not limited to these examples, and any device or medium may be used as long as the device or medium can store the program.

The terminal 20, for example, may read the program stored in the storage device 28 and execute the read program to realize the functions of the plurality of functional units described in the embodiment.

Further, the program of the present inventive concepts may be provided to the server 10 or the terminal 20 via any transmission medium (a communication network, a broadcast wave, or the like) capable of transmitting the program. The server 10 or the terminal 20, for example, may realize the functions of the plurality of functional units described in the above example embodiments by executing the program downloaded via the Internet or the like.

The example embodiments described below can also be realized in the form of a data signal embedded in a carrier wave, the program being embodied by electronic transmission.

It should be noted that a program of the present inventive concepts can be implemented using a script language (e.g., ActionScript, JavaScript (registered trademark)), an object-oriented programming language (e.g., Objective-C), Java (registered trademark), or a markup language (e.g., HTML5). However, the present inventive concepts are not limited thereto.

### First Example Embodiment

A first example embodiment is a form in which a manipulation with respect to the touch panel is not received for a time (e.g., a desired time or a predetermined time) in a case in which the manipulation body that performs a manipulation with respect to the touch panel stops moving on the touch panel. It should be noted that the manipulation body is, for example, a finger of the user or an input pen that is used by the user, and comes in contact with the touch panel to perform a manipulation desired (e.g., a desired manipulation or a predetermined manipulation). Content described in the first example embodiment can be applied to any of the example embodiments to be described below.

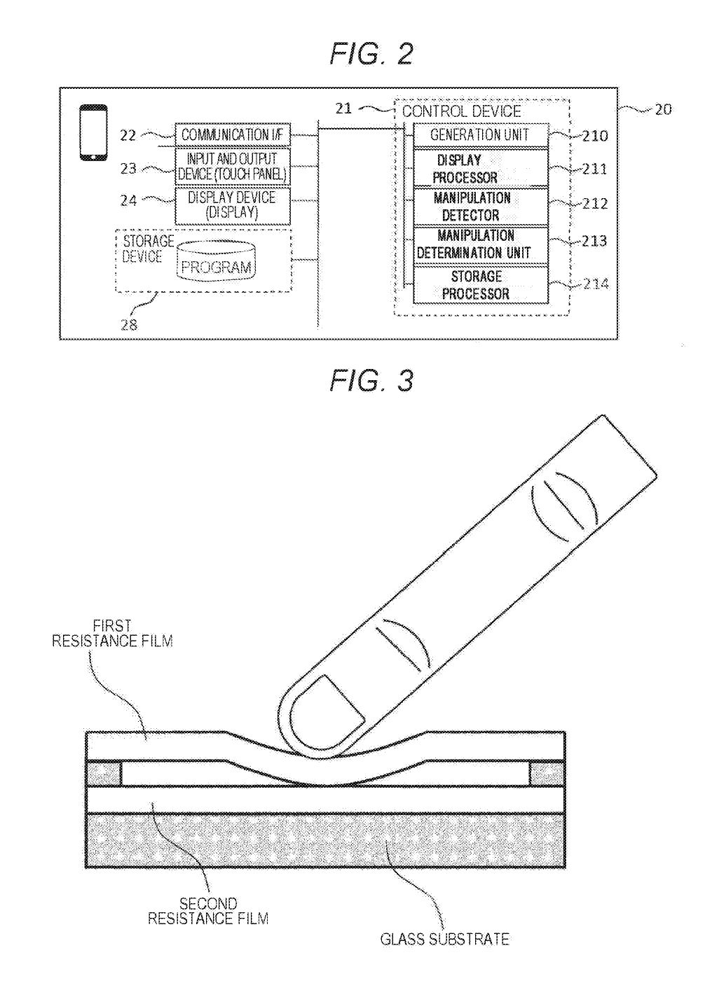

FIG. 2 is a diagram illustrating a configuration example of the terminal 20 according to an example embodiment. As illustrated in FIG. 2, the terminal 20 may include a control device 21, an input and output device 23, a display device 24, and a storage device 28. The control device 21 may include a generation unit (or generation circuit) 210, a display processor (or display processing circuit) 211, a manipulation detector (or manipulation detection circuit) 212, a manipulation determination unit (or manipulation determination circuit) 213, and a storage processor (or storage processing circuit) 214. The units 210, 211, 212, 213, and 214 may refer to functional units of the control device 21. Thus, when the control device is configured by a processor, the processor may be configured to perform various functions corresponding to the functional units 210, 211, 212, 213, and 214.

It should be noted that the input and output device 23 may be, for example, a touch panel (e.g., a pressure sensitive type touch panel or a capacitive touch panel).

The pressure sensitive touch panel may detect a position of a manipulation input to the touch panel by measuring a voltage of electricity generated due to vibration of two electrical resistance films.

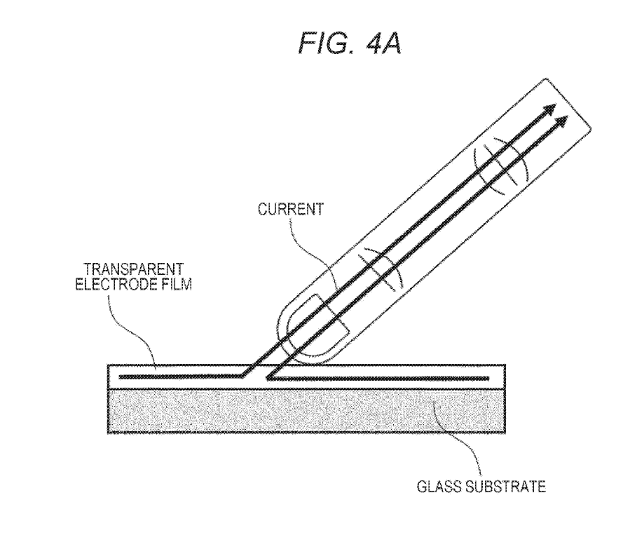

FIG. 3 is a schematic diagram illustrating a cross section of a pressure-sensitive touch panel. As illustrated in FIG. 3, when a manipulation body comes in contact with the touch panel, a first resistance film is bent at a contact point and comes in contact with a second resistance film. In this case, a current flows between the first resistance film and the second resistance film at the contact point and a voltage is generated. The pressure-sensitive touch panel measures the generated voltage, thereby detecting a contact point at which the manipulation body comes in contact with the touch panel.

According to some example embodiments, the touch panel may be a capacitive touch panel. The capacitive touch panel measures a weak current generated when a manipulation body comes in contact with the touch panel with a finger or an input pen (e.g., where there is a change in capacitance), and detects a position of a manipulation input to the touch panel. Examples of the capacitive touch panel include a surface type capacitive touch panel and a projection type capacitive touch panel.

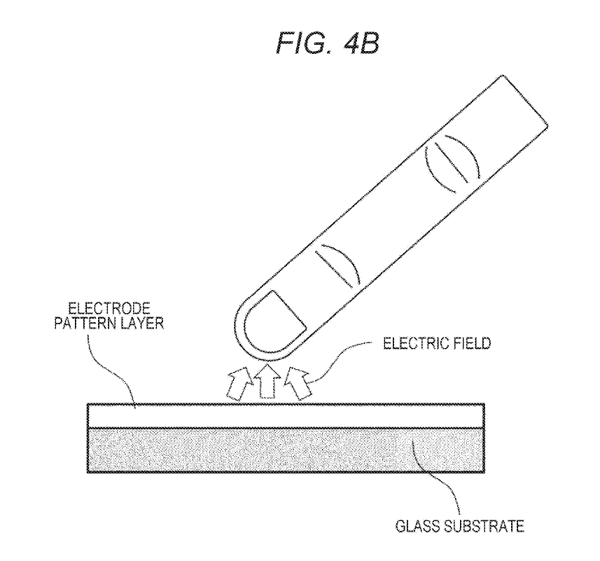

FIG. 4A is a schematic diagram illustrating a cross section of the surface type capacitive touch panel. As illustrated in FIG. 4A, the surface type capacitive touch panel includes a transparent electrode film (a conductive layer), and a voltage is applied to four corners of the transparent electrode film to generate a low voltage electric field throughout the panel. As a result, when a manipulation body comes in contact with the touch panel with a finger or an input pen, a weak current (capacitance) is generated at a contact point. The surface type electrostatic capacitive touch panel measures a change in generated current (capacitance) to detect a contact point at which a manipulation body comes in contact with the touch panel.

Further, FIG. 4B is a schematic diagram illustrating a cross section of the projection type capacitive touch panel. As illustrated in FIG. 4B, the projection type capacitive touch panel may include an electrode pattern layer including a plurality of transparent electrode layers (or films) (conductive layers) having a specific pattern. Thus, when a manipulation body comes in contact with the touch panel with a finger or an input pen, a weak current (capacitance) may be generated in each of the plurality of transparent electrode layers at a contact point. The projection type electrostatic capacitive touch panel may measure the current (capacitance) generated in each of the plurality of transparent electrode layers to detect a contact point at which a manipulation body comes in contact with the touch panel. It should be noted that the projection type capacitive touch panel may include a plurality of transparent electrode layers, and thus the contact point can be measured at a plurality of places, and multi-touch (multiple contacts) can be detected.

In addition to the above touch panel, the touch panel in the present inventive concepts may be an ultrasonic surface acoustic wave type touch panel or an optical type touch panel. The ultrasonic surface acoustic wave type touch panel may output ultrasonic surface acoustic waves transferred as vibration on a panel surface, and the ultrasonic surface acoustic waves may be absorbed and weakened when the ultrasonic surface acoustic waves strike the manipulation body. Therefore, a change in ultrasonic surface acoustic waves may be detected so that the position of the contact point is detected. Further, in the optical type touch panel, for example, an image sensor (a camera) may be disposed for infrared light from an infrared LED, and a shadow of the infrared light shielded due to the manipulation body coming in contact with the touch panel is measured by the image sensor, thereby detecting the position of the contact point.

<Functional Configuration>

(1) Functional Configuration of Terminal

The display processor 211 may display the display data generated by the generation unit 210 via the display device 24. The display processor 211 may have a function of converting display data into pixel information and writing the pixel information to the frame buffer of the display device 24.

The manipulation detector 212 may detect a manipulation input of the manipulation body with respect to the touch panel. The manipulation detector 212 may detect that the manipulation body comes in contact with the touch panel. In this case, the manipulation detector 212 may detect a contact point, which is at a position at which the manipulation body comes in contact with the touch panel, and notify the manipulation determination unit 213 of manipulation content indicating the contact (tap or touch) and the detected position.

Further, for example, the manipulation detector 212 may detect that the manipulation body has moved on the touch panel while the manipulation body comes in contact with the touch panel. In this case, the manipulation detector 212 may detect a trajectory of the movement and notify the manipulation determination unit 213 of manipulation content indicating movement (swiping or sliding) and the detected trajectory. It should be noted that, for example, the manipulation detector 212 may detect a point (start point) at which the manipulation body starts moving on the touch panel and a point (end point) at which the movement ends, and notify the detected start point and stop point to the manipulation determination unit 213.

Further, the manipulation detector 212 may detect, for example, that the manipulation body is separated from the touch panel (e.g., that the manipulation body does not come in contact with the touch panel). In this case, the manipulation detector 212 may detect a position at which the manipulation body is released from the touch panel and notify the manipulation determination unit 213 of content of the release manipulation and the detected position.

It should be noted that the manipulation body coming in contact with the touch panel is represented as, for example, “touch”, the manipulation body moving while coming in contact with the touch panel is represented as, for example, “slide”, and the manipulation body being separated from the touch panel is represented as, for example, “release”.

Further, the manipulation detector 212 may detect that the movement is stopped when the manipulation body stops moving on the touch panel after the manipulation body moves in a state in which the manipulation body comes in contact with the touch panel. The manipulation detector 212 may detect a position at which the manipulation body has stopped and notify the manipulation determination unit 213 of the position. Further, the manipulation detector 212 may detect that the manipulation body has stopped moving once has started moving on the touch panel again. The manipulation detector 212 may detect the position at which the movement is started and notify the manipulation determination unit 213 of the manipulation content indicating that the movement has been restarted and the detected position.

The manipulation determination unit 213, for example, may execute a process corresponding to the manipulation content on the basis of the manipulation content of the manipulation body notified of from the manipulation detector 212 and the manipulation position or the trajectory. The manipulation determination unit 213, for example, may execute a process of selecting an object such as an icon displayed at the contact position on the basis of the manipulation content indicating the contact (tap or touch) and the contact position. Further, the manipulation determination unit 213 may execute a process of moving the selected object (e.g., the icon) on the display on the basis of the manipulation content indicating the movement (swiping or sliding) and the trajectory of the movement. Further, the manipulation determination unit 213, for example, may execute a process corresponding to the object such as the icon displayed at the separated position on the basis of the manipulation content indicating the separation (the release) and the separated position. It should be noted that the functions that are processed by the manipulation determination unit 213 are not limited to these examples and may be any function.

When the manipulation determination unit 213 executes the process corresponding to the manipulation content, the manipulation determination unit 213 may notify the generation unit 210 of content of the process. For example, when the manipulation determination unit 213 may execute the process of selecting the object (e.g., the icon) displayed at the contact position, the manipulation determination unit 213 may notify the generation unit 210 of the content of the process of selecting the icon. Further, when the manipulation determination unit 213 may execute a process of moving the selected object (e.g., the icon) on the display, the manipulation determination unit 213 may notify the generation unit 210 of content of the process of moving the object. When the process executes the process corresponding to the object (e.g., the icon) displayed at a separated position, the manipulation determination unit 213 may notify the generation unit 210 of the content of the process corresponding to the object.

The manipulation determination unit 213, for example, may calculate the elapsed time from the stop on the basis of the manipulation content indicating that the manipulation body has stopped on the touch panel, and the stop position. When the elapsed time from the stop exceeds a time (e.g., a desired time or a predetermined time), the manipulation determination unit 213 may set the invalidation time for invalidating the manipulation with respect to the touch panel. When the invalidation time is set, the manipulation determination unit 213 may not execute the process corresponding to the manipulation content notified from the manipulation determination unit 213 with respect to a manipulation (e.g., a desired manipulation or a predetermined manipulation). The manipulation is, for example, a manipulation with which the manipulation body newly comes in contact with (taps or touches) the touch panel or a process in which the manipulation body moves (swipes or slides) on the touch panel.

For example, in a case in which the invalidation time is set and even when the manipulation determination unit 213 determines that the manipulation body newly comes in contact with (taps or touches) the touch panel within the invalidation time, the process corresponding to the contact (tap or touch) may not be executed. For example, in a case in which the invalidation time is set and even when the manipulation determination unit 213 determines that the manipulation body moves (swipes or slides) on the touch panel within the invalidation time, the process corresponding to the movement (swiping or sliding) may not be executed.

For example, when the elapsed time after the manipulation body stops on the touch panel exceeds a threshold time (e.g., 0.1 second), the manipulation determination unit 213 may set the invalidation time in which the manipulation with respect to the touch panel is invalidated. The time may be calculated on the basis of a function (e.g., a desired function or a predetermined function), or may be any time other than the 0.1 second. Further, the invalidation time may be calculated on the basis of a function (e.g., a desired function or a predetermined function).

It should be noted that even when the invalidation time has been set, the manipulation determination unit 213 may execute the process corresponding to the manipulation at the stop position. For example, when the manipulation body is separated (released) from the touch panel, the manipulation determination unit 213 may execute the process corresponding to the object (e.g., the icon) displayed at the stop position on the basis of the manipulation content indicating the separation (the release) and the stop position.

After the invalidation time has elapsed, the manipulation determination unit 213 may restart the execution of the process corresponding to the manipulation content on the basis of the manipulation content of the manipulation body and the manipulation position or the trajectory notified from the manipulation detector 212.

Further, the manipulation determination unit 213 may notify the storage processor 214 of the manipulation content and the manipulation position or the trajectory notified from the manipulation detector 212 in the invalidation time.

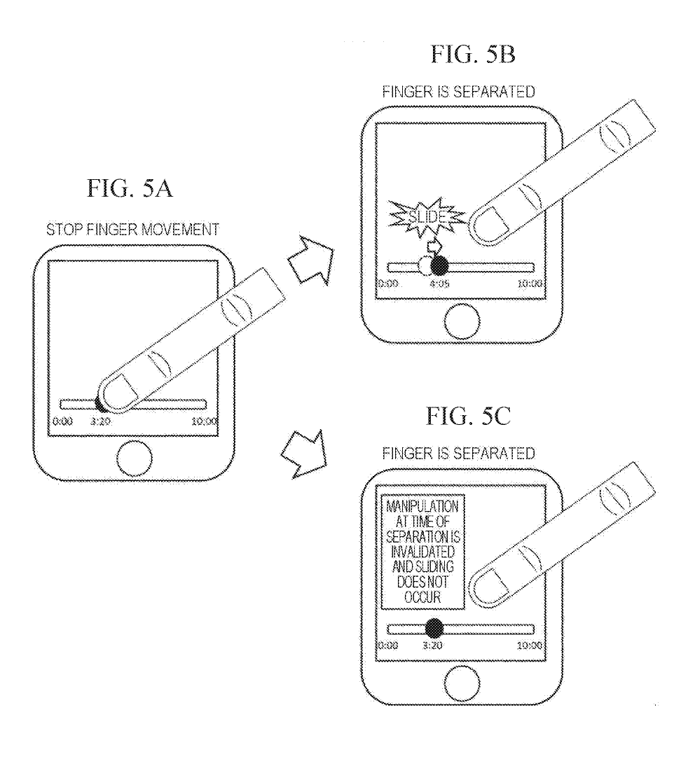

FIGS. 5A, B, and 5C are diagrams illustrating display-content displayed on the touch panel of the terminal according to an example embodiment of the present inventive concepts. FIGS. 5A-5C illustrate examples of manipulations when the user adjusts a playback position using the manipulation body when a moving image is played back at the terminal. As illustrated in FIGS. 5A-5C, the user may operate a “seek bar,” with which the playback position can be adjusted, with the manipulation body to adjust the playback position.

FIG. 5A is an example in which the user adjusts a playback position to a position of “3:20” (3 minutes 20 seconds) by using the seek bar. The user may come in contact with (taps or touches) a cursor on the seek bar using a manipulation body (e.g., a finger) and move (swipe or slide) the cursor to the position of “3:20”. The manipulation body may stop at the position of “3:20” and released from the touch panel at the position and the content at the playback position of “3:20” may be displayed on the display.

FIG. 5B illustrates an example of display-content when the manipulation the invalidation time is not set by the determination unit 213. As illustrated in FIG. 5B, there is a possibility that the manipulation body moves (swipes or slides) on the touch panel when the manipulation body is separated (released) after the manipulation body stops on the touch panel. Further, there is a possibility that the manipulation body newly comes in contact with (taps or touches) the touch panel after the manipulation body is separated. In a case in which the invalidation time is not set, the manipulation determination unit 213 may execute the process corresponding to the manipulation (e.g., sliding or touching) even when the manipulation body is separated (released) after the manipulation body stops on the touch panel.

Thus, as illustrated in FIG. 5B, for example, even when the user intends to separate the manipulation body at the position of “3:20”, the manipulation body may move (swipe or slide) to a position of “4:05”before making a complete separation, and content at the playback position of “4:05,” which has not been intended by the user may be displayed on the display.

When the invalidation time is set, the process corresponding to the manipulation content may be notified from the manipulation determination unit 213 with respect to the manipulation, and thus the manipulation may not be executed.

FIG. 5C illustrates an example of display-content when the invalidation time is not set by the manipulation determination unit 213. As illustrated in FIG. 5C, when the invalidation time is set after the manipulation body stops on the touch panel, a process corresponding to a movement (swiping or sliding) may not be executed even when the manipulation body moves (swipe or slide) on the touch panel at the time of separation (release) of the manipulation body. Further, when the invalidation time is set after the manipulation body stops on the touch panel, a process corresponding to contact (tap or touch) may not be executed even when the manipulation body newly comes in contact with (taps or touches) the touch panel at the time of separation (release) of the manipulation body.

Thus, as illustrated in FIG. 5C, for example, when the user stops the manipulation body at the position of “3:20”, the invalidation time is set and the process corresponding to the following manipulation may not be executed, and only the process corresponding to the separation (release) manipulation may be executed at the position of “3:20”. For example, in a case in which the user stops the manipulation body at the position of “3:20” for more than the invalidation time, the process corresponding to the following manipulation may not be executed even when the manipulation body moves (swipes or slides) to the position of “4:05” before making a complete separation, and only the process corresponding to the separation (release) manipulation at a point in time at which the user stops the manipulation body may be executed at the position of “3:20”. Thus, the content at the playback position of “3:20” intended by the user may be displayed on the display.

Thus, by the manipulation determination unit 213 setting the invalidation time, a process corresponding to the manipulation content notified from the manipulation determination unit 213 may not be executed with respect to a certain unwanted manipulation. Thus, it is possible to prevent an erroneous manipulation of the user.

The storage processor 214 may execute a process of storing, in the storage device 28, the manipulation content and the manipulation position or the trajectory within the invalidation time notified when the invalidation time is set by the manipulation determination unit 213. For example, the storage processor 214 may execute a process of storing, in the storage device 28, the manipulation content indicating the movement (swiping or sliding) of the manipulation body on the touch panel within the invalidation time and the trajectory of the movement notified from the manipulation determination unit 213.

The generation unit 210 may generate display data to be displayed on the display in correspondence to the process content notified from the manipulation determination unit 213. The generation unit 210, for example, may generate display data indicating that the icon has been selected in correspondence to the process content indicating the icon selection, or the generation unit 210 may generate display data indicating a state in which the object (e.g., the icon) moves in correspondence to the process content indicating that the selected object moves on the display. Further, the generation unit 210 may generate display data indicating process content associated with the object in correspondence to the process content corresponding to the object.

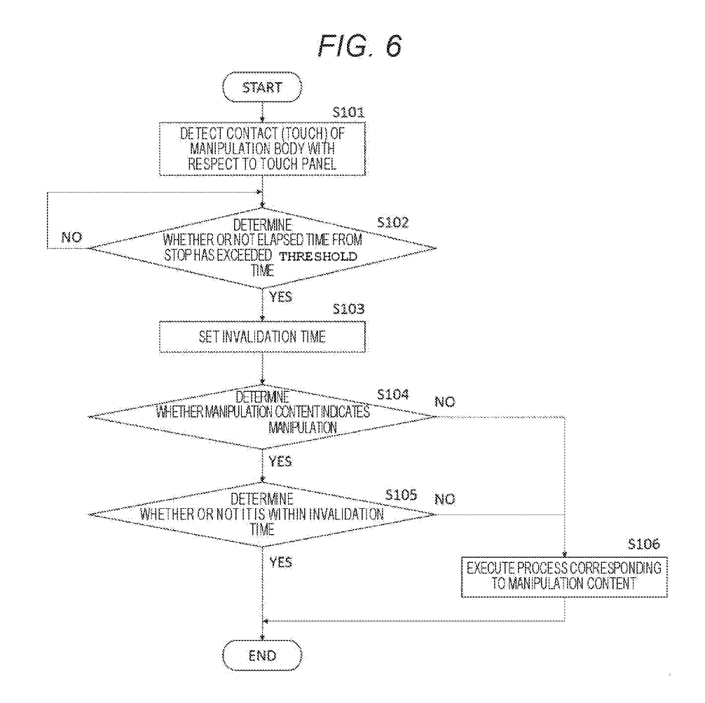

FIG. 6 is a flowchart showing an example of an operation of the terminal according to an example embodiment.

The manipulation detector 212 of the terminal may detect contact (tap or touch) of the manipulation body with respect to the touch panel (S101).

Then, the manipulation determination unit 213 may determine whether or not the elapsed time from the stop has exceeded a time (e.g., a threshold time, a desired time, or a predetermined time) when the manipulation body stops on the touch panel (S102).

When the manipulation determination unit 213 determines that the elapsed time from the stop exceeds the time (YES in S102), the manipulation determination unit 213 may set the invalidation time (S103). When the elapsed time from the stop has not exceeded the predetermined time (NO in S102), the manipulation determination unit 213 may return to S102.

The manipulation determination unit 213 may determine whether the manipulation content notified from the manipulation detector 212 indicates a manipulation (e.g., a desired manipulation or a predetermined manipulation) (S104). In this case, when the manipulation content notified from the manipulation detector 212 is a desired (or alternatively predetermined) manipulation such as a movement (e.g., swiping or sliding) or a contact (e.g., tap or touch) manipulation) (YES in S104), the process may proceed to S105. When the manipulation content notified from the manipulation detector 212 is not the desired (or alternatively, predetermined) manipulation content (NO in S104), the manipulation determination unit 213 may execute the process corresponding to the notified manipulation content (for example, a separation (release) manipulation) (S106). It should be noted that the process of S104 may be omitted, and the manipulation determination unit 213 may proceed to the process of S105 after the process of S103.

When the manipulation content is notified from the manipulation detector 212, the manipulation determination unit 213 may determine whether or not it is within the set invalidation time (S105). When the notification of the manipulation content is within the invalidation time (YES in S105), the manipulation determination unit 213 may not execute the process corresponding to the notified manipulation content and end the process. When the notification of the manipulation content is after the invalidation time has elapsed, the manipulation determination unit 213 may execute a process corresponding to the manipulation content (S106) and end the process.

It should be noted that a function of invalidating the manipulation within the invalidation time may be implemented by an application programming interface (API) or may be implemented by application software (APP). When the function of invalidating the manipulation is implemented in the API, the API notifies the APP of the invalidated manipulation content and coordinates of the manipulation position or the trajectory. For example, when the function of invalidating the manipulation is implemented in the APP, the APP may acquire the coordinates of the manipulation position from an operating system (OS) and executes an invalidation process.

### First Modification Example

In a first modification example, the manipulation determination unit 213 may set the invalidation time on the basis of a function (e.g., a desired function or a predetermined function) and/or on the basis of an elapsed time after the manipulation body stops on the touch panel.

For example, when the elapsed time after the manipulation body stops on the touch panel is N seconds, the manipulation determination unit 213 may set the invalidation time to “N/10” seconds. For example, when the elapsed time after the manipulation body stopped on the touch panel is “0.1” second, the manipulation determination unit 213 may set the invalidation time to “0.1/10=0.01” seconds. It should be noted that the function set for the manipulation detector 212 to set the invalidation time is not limited to “N/10”, and any time may be used.

### Second Modification Example

In a second modification example, when the movement is restarted after the movement of the manipulation body is once stopped, and the movement may continue beyond the invalidation time, the manipulation content within the invalidation time is displayed on the display.

As described above, the manipulation determination unit 213 may notify the storage processor 214 of the manipulation content and the manipulation position or the trajectory notified from the manipulation detector 212 in the invalidation time. The storage processor 214 may execute a process of storing the manipulation content and the manipulation position or the trajectory within the invalidation time in the storage device 28.

When the movement is restarted after the movement of the manipulation body is once stopped, and the movement may continue beyond the invalidation time, the manipulation determination unit 213 may request the generation unit 210 to generate display data to be displayed on the display by referring to the manipulation content at the invalidation time from the storage device 28.

When there is a request from the manipulation determination unit 213, the generation unit 210 may generate display data for displaying the manipulation content in the invalidation time on the display.

Thus, when the movement is restarted after the movement of the manipulation body is once stopped, and the movement may continue beyond the invalidation time, and the manipulation content within the invalidation time may be displayed on the display.

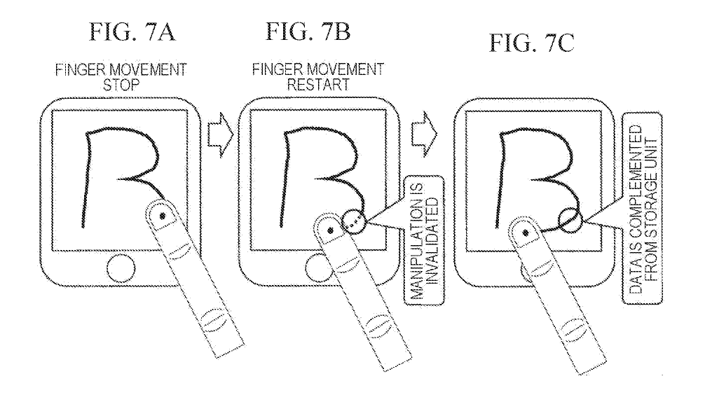

FIGS. 7A, 7B, and 7C are diagrams illustrating display-content displayed on the touch panel of the terminal according to an example embodiment of the present inventive concepts. FIGS. 7A-7C illustrates a case in which an image, a memo, or the like is input by the manipulation body at a terminal, and illustrates, for example, a hand-drawn memo software.

Referring to FIG. 7A-7C, the user is drawing an alphabet “B” with the manipulation body using the hand-drawn memo software. The user moves the manipulation body such as a finger on the touch panel and draws an alphabet “B”.

FIG. 7A illustrates display-content in a case in which movement of the manipulation body has once stopped. In this case, the manipulation determination unit 213 may set the invalidation time.

FIG. 7B illustrates display-content when the manipulation body restarts movement within the invalidation time. As illustrated in FIG. 7B, when the invalidation time is set after the manipulation body stops on the touch panel, a process corresponding to the movement (swiping or sliding) may not be executed even when the manipulation body moves (swipes or slides) on the touch panel. Therefore, even when the manipulation body such as a finger is moved on the touch panel, the process corresponding to the movement may not be executed. Thus, a portion corresponding to the movement may not be displayed on the display, a character “B” is cut off halfway.

Therefore, when the movement of the manipulation body is restarted after the movement is once stopped, and the movement may continue beyond the invalidation time, the manipulation content at the invalidation time may be referred to from the storage device 28 and displayed on the display.

FIG. 7C illustrates display-content when the manipulation content at the invalidation time is referred to from the storage device 28 and displayed on the display. As illustrated in FIG. 7C, the trajectory of the movement of the manipulation body at the invalidation time stored in the storage device 28 may be displayed on the display. Thus, even when the manipulation body restarts the movement within the invalidation time, it is possible to prevent a manipulation portion within the invalidation time from being not displayed, or cause the manipulation content within the invalidation time to be displayed referring to the storage device 28. In other words, the process content corresponding to the detected manipulation, which is associated with the restarting movement, and the stored information may be executed when the restarting movement exceeds the invalidation time. Thus, it is possible to perform a display corresponding to the manipulation content of the user. Accordingly, the user can visually recognize a history of manipulation at the invalidation time.

### Third Modification Example

In a third modification example, the manipulation determination unit 213 may set the invalidation range in addition to the invalidation time.

When the elapsed time from the stop exceeds a time (e.g., a desired time or a predetermined time), the manipulation determination unit 213 may invalidate a manipulation (e.g., a desired manipulation or a predetermined manipulation) with respect to the touch panel within a range (e.g., a desired range or a predetermined range) from the stopped position. That is, when the elapsed time from the stop exceeds the time, the manipulation determination unit 213 may set an invalidation range in which the manipulation with respect to the touch panel may be invalidated, in addition to the invalidation time for invalidating the manipulation with respect to the touch panel.

When the invalidation range has been set, the manipulation determination unit 213 may not execute the process corresponding to the manipulation content notified from the manipulation determination unit 213 with respect to the manipulation within the invalidation range. The manipulation is, for example, a manipulation in which the manipulation body newly comes in contact with (taps or touches) the touch panel, or a process in which the manipulation body moves (swipes or slides) on the touch panel.

The invalidation range may be, for example, a range having a size (e.g., a desired size or a predetermined size) or a range having a size determined on the basis of a function (e.g., a desired function or a predetermined function). The invalidation range may be an entire area of touch panel. Further, the invalidation range may have any shape, and may be, for example, circular or square.

When the invalidation time and the invalidation range have been set, the manipulation determination unit 213 may not execute a process corresponding to the manipulation content notified from the manipulation determination unit 213 with respect to a manipulation (e.g.,, a desired manipulation or a predetermined manipulation) within the invalidation range at the invalidation time. The manipulation is, for example, a manipulation in which the manipulation body newly comes in contact with (taps or touches) the touch panel, or a process in which the manipulation body moves (swipes or slides) on the touch panel.

It should be noted that even when the invalidation time and the invalidation range are set, the manipulation determination unit 213 may execute a process corresponding to the manipulation at the stop position. For example, in a case in which the manipulation body is separated (released) from the touch panel at the stop position, the manipulation determination unit 213 may execute a process corresponding to the object (e.g., the icon) displayed at the stop position on the basis of the manipulation content indicating the separation (the release). Further, when the invalidation time and the invalidation range are set, the manipulation determination unit 213 may execute the process corresponding to the manipulation outside the invalidation range. For example, when the manipulation body is separated (released) from the touch panel outside the invalidation range, the manipulation determination unit 213 may execute the process corresponding to the object on the basis of the manipulation content indicating the separation (the release).

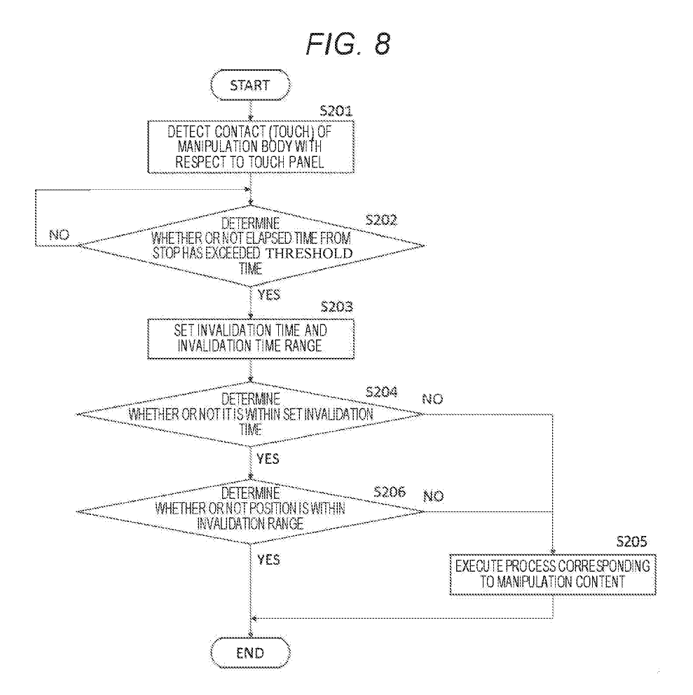

FIG. 8 is a flowchart showing an example of operations of the terminal in the third modification example of the first embodiment.

The manipulation detector 212 of the terminal may detect the contact (touch) of the manipulation body with respect to the touch panel (S201), detect a position at which the manipulation body is released from the touch panel, and notify the manipulation notification unit of manipulation content indicating the separation (release) and the detected position.

Then, the manipulation determination unit 213 may determine whether or not the elapsed time from the stop has exceeded a time (e.g., a threshold time, a desired time, or a predetermined time) when the manipulation body stops on the touch panel (S202).

When the manipulation determination unit 213 determines that the elapsed time from the stop exceeds the time (YES in S202), the manipulation determination unit 213 may set the invalidation time and an invalidation range (S203). When the elapsed time from the stop has not exceeded the time (NO in S202), the manipulation determination unit 213 may return to S202.

When a manipulation content (e.g., desired manipulation content or predetermined manipulation content) is notified from the manipulation detector 212, the manipulation determination unit 213 may determine whether or not it is within the set invalidation time (S204). When the notification of the manipulation content is after the invalidation time has elapsed, the manipulation determination unit 213 may execute the manipulation content (S205), and end the manipulation.

When the notification of the manipulation content is within the invalidation time (YES in S204), the manipulation determination unit 213 may determine whether or not the manipulation position notified from the manipulation detector 212 is within the set invalidation range (S206). When the manipulation position is within the invalidation range (YES in S206), the manipulation determination unit 213 may not execute the process corresponding to the manipulation content, and end the process. When the manipulation position is outside the invalidation range or when the manipulation position is the stop position (NO in S206), the manipulation determination unit 213 may execute the manipulation content (S205) and end.

By the manipulation determination unit 213 setting the invalidation time and the invalidation range, the process corresponding to the manipulation content executed within the invalidation range may not be executed within the invalidation time. Therefore, it is possible to prevent an erroneous manipulation of the user.

As described above, by the manipulation determination unit 213 setting the invalidation time, the process corresponding to the manipulation content notified from the manipulation determination unit 213 with respect to the predetermined manipulation may not be executed. Therefore, it is possible to prevent an erroneous manipulation of the user.

### Second Example Embodiment

A second example embodiment is a form in which a manipulation within a range (e.g., a desired range or a predetermined range) from the stopped position is not received in a case in which the manipulation body that performs a manipulation with respect to the touch panel stops movement on the touch panel. Content described in the second example embodiment can be applied to any of the other example embodiments.

In the second example embodiment, the manipulation determination unit 213 of the terminal, for example, may calculate the elapsed time from the stop on the basis of the manipulation content indicating that the manipulation body has stopped on the touch panel, and the stop position. When the elapsed time from the stop exceeds a time (e.g., a desired time or a predetermined time), the manipulation determination unit 213 may invalidate a manipulation (e.g., a desired manipulation or a predetermined manipulation) with respect to the touch panel within the range from the stopped position. That is, when the elapsed time from the stop exceeds the time, the manipulation determination unit 213 may set an invalidation range in which the manipulation with respect to the touch panel is invalidated.

When the invalidation range has been set, the manipulation determination unit 213 may not execute the process corresponding to the manipulation content notified from the manipulation determination unit 213 with respect to the manipulation within the invalidation range. The manipulation is, for example, a manipulation in which the manipulation body newly comes in contact with (taps or touches) the touch panel, or a process in which the manipulation body moves (swipes or slides) on the touch panel.

For example, in a case in which the invalidation range is set and even when the manipulation determination unit 213 may determine that the manipulation body newly comes in contact with (taps or touches) the touch panel within the invalidation range, the process corresponding to the contact (tap or touch) may not be executed. For example, in a case in which the invalidation range is set and the manipulation determination unit 213 determines that the manipulation body moves (swipes or slides) on the touch panel within the invalidation range, the process corresponding to the movement (swiping or sliding) may not be executed.

The invalidation range may be, for example, a range having a size (e.g., a desired size or a predetermined size) or a range having a size determined on the basis of a function (e.g., a desired function or a predetermined function). The invalidation range may be an entire area of the touch panel. Further, the invalidation range may have any shape, and may be, for example, circular or square.

For example, when the elapsed time after the manipulation body stops on the touch panel exceeds 0.1 seconds which is a time (e.g., a desired time or a predetermined time), the manipulation determination unit 213 may set the invalidation range in which the manipulation with respect to the touch panel is invalidated. The time may be a time calculated on the basis of a function (e.g., a desired function or a predetermined function), or may be any time other than the 0.1 seconds. Further, the invalidation time may be a time calculated on the basis of a function (e.g., a desired function or a predetermined function).

It should be noted that when the invalidation range has been set, the manipulation determination unit 213 may execute the process corresponding to the manipulation at the stop position. For example, in a case in which the manipulation body is separated (released) from the touch panel at the stop position, the manipulation determination unit 213 may execute the process corresponding to the object (e.g., the icon) displayed at the stop position on the basis of the manipulation content indicating the separation (the release). Further, when the invalidation range has been set, the manipulation determination unit 213 may execute the process corresponding to the manipulation outside the invalidation range. For example, when the manipulation body is separated (released) from the touch panel outside the invalidation range, the manipulation determination unit 213 may execute the process corresponding to the object on the basis of the manipulation content indicating the separation (the release).

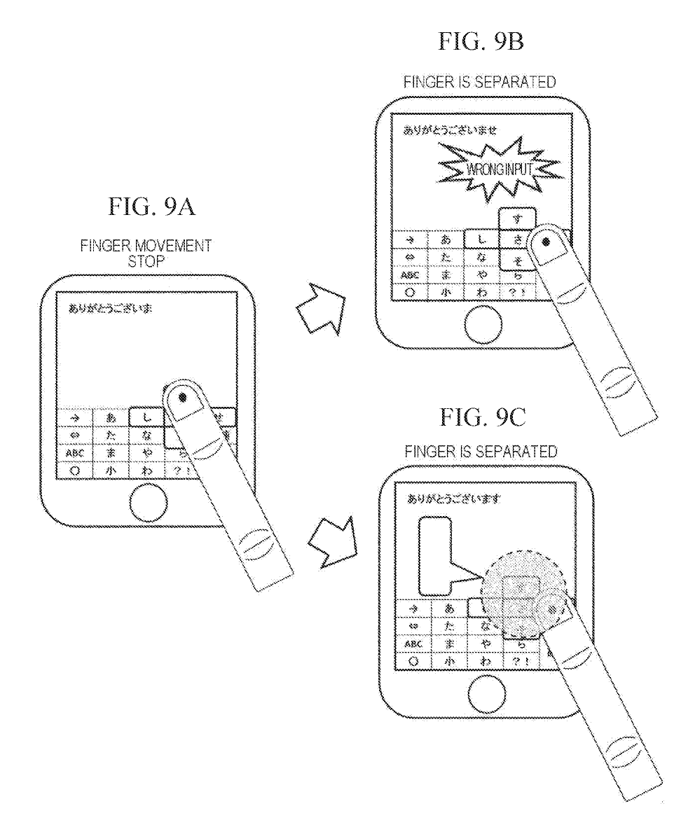

FIGS. 9A, 9B, and 9C are diagrams illustrating display-content displayed on the touch panel of the terminal according to the second embodiment of the present inventive concepts. FIGS. 9A-9C illustrate an example of a manipulation in a case in which the user inputs characters in the terminal. As illustrated in FIGS. 9A-9C, the user may select characters on a keyboard displayed on the display in order to input the characters. FIGS. 9A-9C is illustrated with an example of Japanese keyboard, but example embodiments of the present inventive concepts are not limited thereto. In some example embodiments, the inventive concepts may be applied to English keyboard, Chinese keyboard, Korean keyboard, etc.

Referring to FIG. 9A, the user comes in contact with (taps or touches) a position of “ [symbol] ” on the keyboard with the manipulation body to select “ [symbol] ” in order to input “ [symbol] ”.

FIG. 9B illustrates an example of display-content when the invalidation range is not set by the manipulation determination unit 213. As illustrated in FIG. 9B, there is a possibility that the manipulation body moves (swipes or slides) on the touch panel when the manipulation body is separated (released) after the manipulation body stops on the touch panel. Further, there is a possibility that the manipulation body newly comes in contact with (taps or touches) the touch panel after the manipulation body is separated. In a case in which the invalidation range is not set, the manipulation determination unit 213 may execute the process corresponding to the manipulation (e.g., swiping, sliding, tapping, or touching) when the manipulation body is separated (released) after the manipulation body stops on the touch panel.

Referring to FIG. 9B, for example, even when the user intends to separate the manipulation body at a position of “ [symbol] ”, the manipulation body before the separation may move (e.g., swipe or slide) to the position of “ [symbol] ”, and “ [symbol] ” not intended by the user may be input.

When the invalidation range is set, however, the process corresponding to the manipulation content notified from the manipulation determination unit 213 with respect to the manipulation within the invalidation range may not be executed.

FIG. 9C illustrates an example of display-content when the manipulation determination unit 213 sets the invalidation range. As illustrated in FIG. 9C, when the invalidation range is set after the manipulation body stops on the touch panel, a process corresponding to a movement (e.g., swiping or sliding) may not be executed even when the manipulation body moves (swipes or slides) on the touch panel at the time of separation (release) of the manipulation body. Further, when the invalidation range is set after the manipulation body stops on the touch panel, a process corresponding to contact (e.g., tap or touch) may not be executed even when the manipulation body newly comes in contact with (e.g., taps or touches) the touch panel at the time of separation (release) of the manipulation body.

Thus, as illustrated in FIG. 9C, for example, when the user stops the manipulation body at a position of “ [symbol] ”, the invalidation range is set and the process corresponding to the manipulation within the invalidation range may not be executed. Thus, only a process corresponding to the separation (release) manipulation at the position of “ [symbol] ” may be executed. In a case in which the user separates the manipulation body at the position of “ [symbol] ”, the process corresponding to the manipulation (e.g., a manipulation after the user has made a stop at a position of “ [symbol] ”) may not be executed even when the manipulation body moves (e.g., swipes or slides) to a position of “ [symbol] ” before the separation, and only a process of separation (release) at the position of “ [symbol] ” may be executed, and “ [symbol] ” intended by the user may be inputted.

Thus, by the manipulation determination unit 213 setting the invalidation range, a process corresponding to the manipulation content (e.g., manipulation content associated with the use's manipulation after the user has made a stop at a certain position) notified from the manipulation determination unit 213 may not be executed within the invalidation range. Therefore, it is possible to reduce or prevent erroneous manipulation of the user.

When the invalidation range is set by the manipulation determination unit 213, the storage processor 214 may execute a process for storing the manipulation content and the manipulation position or the trajectory within the invalidation range in the storage device 28. For example, the storage processor 214 may execute a process of storing, in the storage device 28, the manipulation content indicating the movement (swiping or sliding) of the manipulation body on the touch panel within the invalidation range and the trajectory of the movement notified from the manipulation determination unit 213.

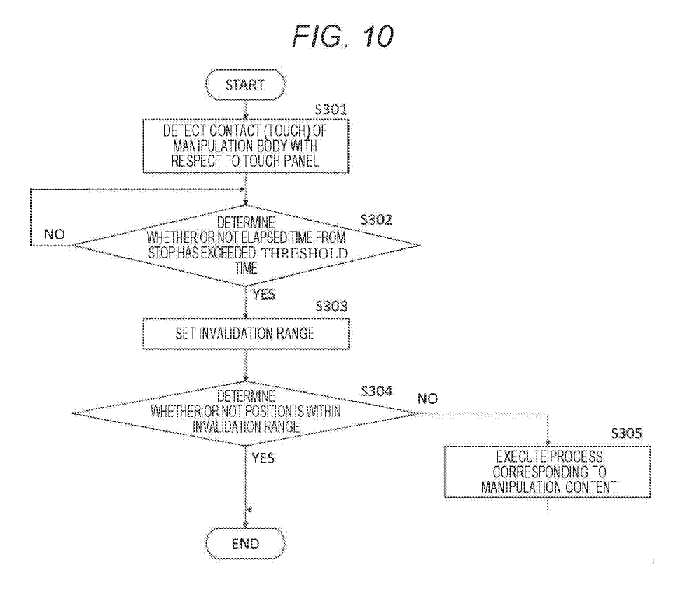

FIG. 10 is a flowchart showing an example of an operation of the terminal according to an example embodiment.

The manipulation detector 212 of the terminal may detect a contact (e.g., tap or touch) of the manipulation body with respect to the touch panel (S301), detect a position at which the manipulation body is released from the touch panel, and notify the manipulation notification unit of manipulation content indicating the separation (release) and the detected position.

Then, the manipulation determination unit 213 may determine whether or not the elapsed time from the stop has exceeded a time (e.g., a threshold time, a desired time, or a predetermined time) when the manipulation body stops on the touch panel (S302).

When the manipulation determination unit 213 determines that the elapsed time from the stop exceeds the time (YES in S302), the manipulation determination unit 213 may set the invalidation range (S303). When the elapsed time from the stop has not exceeded the time (NO in S302), the manipulation determination unit 213 may return to S302.

The manipulation determination unit 213 may determine whether or not the manipulation position notified from the manipulation detector 212 is within the set invalidation range (S304). When the manipulation position is within the invalidation range (YES in S304), the manipulation determination unit 213 may not execute the process corresponding to the manipulation content (e.g., manipulation content associated with the use's manipulation after the user has made a stop at a certain position), and end the process. When the manipulation position is outside the invalidation range or when the manipulation position is the stop position (NO in S304), the manipulation determination unit 213 may execute the manipulation content associated with the use's manipulation after the user has made a stop at a certain position (S305), and end.

### First Modification Example

In a first modification example, the manipulation detector 212 may set the invalidation range using a function (e.g., a desired function or a predetermined function) on the basis of a distance by which the manipulation body has moved until the manipulation body stops on the touch panel.

For example, when the movement distance of the manipulation body until the manipulation body stops is relatively long, the manipulation determination unit 213 may set the invalidating range to be relatively wide, and when the movement distance of the manipulation body until the manipulation body stops is relatively short, the manipulation determination unit 213 may set the invalidating range to be relatively narrow.

For example, when the movement distance until the manipulation body stops on the touch panel is “N” pixels, the manipulation determination unit 213 may set the invalidation range to a range of “N/100” pixels. For example, when the movement distance until the manipulation body stops on the touch panel is “1000” pixels, the manipulation detector 212 may set the invalidation range to a circular range of diameter “1000/100=10” pixels centered on the stop position. It should be noted that the function used for the manipulation detector 212 to set the invalidation range is not limited to “N/100”, and any function may be used

As described above, by the manipulation determination unit 213 setting the invalidation range, a process corresponding to the manipulation content (e.g., manipulation content associated with the use's manipulation after the user has made a stop at a certain position) notified from the manipulation determination unit 213 may not be executed within the invalidation range. Therefore, it is possible to reduce or prevent erroneous manipulation of the user.

### Second Modification Example

In a second modification example, when the manipulation body restarts the movement after stopping the movement once, and continues to move beyond the invalidation range, the manipulation content within the invalidation range may be displayed on the display.

As described above, the manipulation determination unit 213 may notify the storage processor 214 of the manipulation content, and the manipulation position or the trajectory notified from the manipulation detector 212 within the invalidation range. The storage processor 214 may execute the process of storing the manipulation content and the manipulation position or the trajectory within the invalidation range in the storage device 28.

When the manipulation body restarts the movement after stopping the movement once, and continues to move beyond the invalidation range, the manipulation determination unit 213 may request the generation unit 210 to generate display data to be displayed on the display by referring to the manipulation content within the invalidation range from the storage device 28.

When there is a request from the manipulation determination unit 213, the generation unit 210 may generate the display data for displaying the manipulation content within the invalidation range on the display.

Accordingly, when the manipulation body restarts the movement after stopping the movement once, and continues to move beyond the invalidation range, the manipulation content within the invalidation range may be displayed on the display. Thus, it is possible to reduce or prevent a manipulation portion within the invalidation range from being not displayed, or cause a uniform display to be performed, Further, it is possible to perform a display corresponding to the manipulation content of the user.

### Third Modification Example

In a third modification example, the manipulation determination unit 213 may set the invalidation time, in addition to the invalidation range.

When the elapsed time from the stop exceeds a time (e.g., a desired time or a predetermined time), the manipulation determination unit 213 may set the invalidation time for invalidating a manipulation (e.g., a desired manipulation or a predetermined manipulation) with respect to the touch panel. When the invalidation time is set, the manipulation determination unit 213 may not execute the process corresponding to the manipulation content notified from the manipulation determination unit 213 with respect to the manipulation. The manipulation is, for example, a manipulation with which the manipulation body newly comes in contact with (e.g., taps or touches) the touch panel or a process in which the manipulation body moves (e.g., swipes or slides) on the touch panel.

For example, in a case in which the invalidation time is set and the manipulation determination unit 213 determines that the manipulation body newly comes in contact with (e.g., taps or touches) the touch panel within the invalidation time, the process corresponding to the contact (e.g., tap or touch) may not be executed. For example, in a case in which the invalidation time is set and the manipulation determination unit 213 determines that the manipulation body moves (e.g., swipes or slides) on the touch panel within the invalidation time, the process corresponding to the movement (e.g., swiping or sliding) may not be executed.

For example, when the elapsed time after the manipulation body stops on the touch panel is N seconds, the manipulation detector 212 may set the invalidation time to “N/10” seconds. For example, when the elapsed time after the manipulation body stopped on the touch panel is “0.1” seconds, the manipulation detector 212 may set the invalidation time to “0.1/10=0.01” seconds. It should be noted that the function set for the manipulation detector 212 to set the invalidation time may not limited, and any function may be used.

When the invalidation time and the invalidation range have been set, the manipulation determination unit 213 may not execute a process corresponding to the manipulation content notified from the manipulation determination unit 213 with respect to a manipulation (e.g., a desired manipulation or a predetermined manipulation)within the invalidation range at the invalidation time. The manipulation may be, for example, a manipulation in which the manipulation body newly comes in contact with (taps or touches) the touch panel, or a process in which the manipulation body moves (swipes or slides) on the touch panel.

It should be noted that even when the invalidation time and the invalidation range are set, the manipulation determination unit 213 may execute a process corresponding to the manipulation at the stop position. For example, in a case in which the manipulation body is separated (released) from the touch panel at the stop position, the manipulation determination unit 213 may execute a process corresponding to the object (e.g., the icon) displayed at the stop position on the basis of the manipulation content indicating the separation (the release). Further, when the invalidation time and the invalidation range are set, the manipulation determination unit 213 may execute the process corresponding to the manipulation outside the invalidation range. For example, when the manipulation body is separated (released) from the touch panel outside the invalidation range, the manipulation determination unit 213 may execute the process corresponding to the object on the basis of the manipulation content indicating the separation (e.g., the release).

Because the example of the operation of the terminal in the third modification example of the second example embodiment is the same as the example of the operation illustrated in FIG. 8, detailed description thereof will be omitted.

By the manipulation determination unit 213 setting the invalidation time and the invalidation range, the process corresponding to the manipulation content executed within the invalidation range may not be executed within the invalidation time. Therefore, it is possible to reduce or prevent an erroneous manipulation of the user.

### Third Example Embodiment

The third example embodiment is an embodiment in which the manipulation determination unit 213 sets an invalidation range in which the manipulation is invalidated according to a stop time of the manipulation body on the touch panel. Content described in the third example embodiment can be applied to any of the other example embodiments.

In the third example embodiment, the manipulation determination unit 213 of the terminal, for example, may calculate the elapsed time from the stop on the basis of the manipulation content indicating that the manipulation body has stopped on the touch panel, and the stop position. When the elapsed time from the stop exceeds a time (e.g., a desired time or a predetermined time), the manipulation determination unit 213 may set an invalidation range in which a manipulation (e.g., a desired manipulation or a predetermined manipulation) with respect to the touch panel is invalidated within a range (e.g., a desired range or a predetermined range) from the stopped position. That is, when the elapsed time from the stop exceeds the time, the manipulation determination unit 213 may set the invalidation range in which the manipulation with respect to the touch panel is invalidated according to the elapsed time.

In the third example embodiment, the manipulation determination unit 213 may set the invalidation range in which the manipulation is invalidated according to the stop time of the manipulation body on the touch panel. For example, when the elapsed time after the manipulation body stops on the touch panel increases, the manipulation determination unit 213 may set the invalidation range to be wider. For example, when the elapsed time after the manipulation body stops on the touch panel decreases, the manipulation determination unit 213 may set the invalidation range to be narrower.

When the invalidation range has been set, the manipulation determination unit 213 may not execute the process corresponding to the manipulation content notified from the manipulation determination unit 213 with respect to the manipulation within the invalidation range. The manipulation is, for example, a manipulation in which the manipulation body newly comes in contact with (e.g., taps or touches) the touch panel, or a process in which the manipulation body moves (e.g., swipes or slides) on the touch panel.

For example, even when the manipulation determination unit 213 determines that the manipulation body newly comes in contact with (taps or touches) the touch panel within the invalidation range, the process corresponding to the contact (tap or touch) may not be executed. For example, even when the manipulation determination unit 213 determines that the manipulation body moves (e.g., swipes or slides) on the touch panel within the invalidation range, the process corresponding to the movement (e.g., swiping or sliding) may not be executed.

The invalidation range may be, for example, a range having a desired (or alternatively, predetermined) size or a range having a size determined on the basis of a function (e.g., a desired function or a predetermined function). The invalidation range may be the entire touch panel. Further, the invalidation range may have any shape, and may be, for example, circular or square.

For example, when the elapsed time after the manipulation body stops on the touch panel exceeds a time of, for example, 0.1 second, the manipulation determination unit 213 may set the invalidation range in which the manipulation with respect to the touch panel is invalidated. The time may be calculated on the basis of a function (e.g., a desired function or a predetermined function), and may be any time other than the 0.1 second.

It should be noted that even when the invalidation range is set, the manipulation determination unit 213 may execute a process corresponding to the manipulation at the stop position. For example, in a case in which the manipulation body is separated (released) from the touch panel at the stop position, the manipulation determination unit 213 may execute a process corresponding to the object (e.g., the icon_displayed at the stop position on the basis of the manipulation content indicating the separation (the release). Further, when the invalidation range is set, the manipulation determination unit 213 may execute the process corresponding to the manipulation outside the invalidation range. For example, when the manipulation body is separated (released) from the touch panel outside the invalidation range, the manipulation determination unit 213 may execute the process corresponding to the object on the basis of the manipulation content indicating the separation (the release).

### First Modification Example

In a first modification example, the manipulation determination unit 213 may set the invalidation range on the basis of a function (e.g., a desired function or a predetermined function) on the basis of the elapsed time after the manipulation body stops on the touch panel. The function may be any function.

For example, when the elapsed time after the manipulation body stops on the touch panel is N seconds, the manipulation determination unit 213 may set a range of “100×N” pixels from the stop position as the invalidation range. For example, when the invalidation range is set in a circular shape, the manipulation determination unit 213 sets a range of a radius of “100×N” pixels from the stop position as the invalidation range.

For example, when the elapsed time after the manipulation body stops on the touch panel is “0.1” seconds, the manipulation determination unit 213 may set the invalidation range to “100×0.1=10” pixels. It should be noted that the function used for the manipulation determination unit 213 to set the invalidation time is not limited, and any function may be used.

### Second Modification Example

In a second modification example, when the movement is continued beyond the invalidation range, the manipulation content within the invalidation range may be displayed on the display.

The manipulation determination unit 213 may notify the storage processor 214 of the manipulation content, and the manipulation position or the trajectory notified from the manipulation detector 212 within the invalidation range. The storage processor 214 may execute the process of storing the manipulation content and the manipulation position or the trajectory within the invalidation range in the storage device 28.

When the manipulation body restarts the movement after stopping the movement once, and continues to move beyond the invalidation range, the manipulation determination unit 213 may request the generation unit 210 to generate display data to be displayed on the display by referring to the manipulation content within the invalidation range from the storage device 28.

When there is a request from the manipulation determination unit 213, the generation unit 210 may generate the display data for displaying the manipulation content within the invalidation range on the display.

Accordingly, when the manipulation body restarts the movement after stopping the movement once, and continues to move beyond the invalidation range, the manipulation content within the invalidation range may be displayed on the display. Thus, it is possible to reduce or prevent a manipulation portion within the invalidation range from being not displayed, or cause a uniform display to be performed. Further, it is possible to perform a display corresponding to the manipulation content of the user.

### Third Modification Example

In a third modification example, the manipulation determination unit 213 may set the invalidation time, in addition to the invalidation range.

When the elapsed time from the stop exceeds a time (e.g., a desired time or a predetermined time), the manipulation determination unit 213 sets the invalidation time for invalidating the manipulation (e.g., a desired manipulation or a predetermined manipulation) with respect to the touch panel. When the invalidation time is set, the manipulation determination unit 213 may not execute the process corresponding to the manipulation content notified from the manipulation determination unit 213 with respect to a predetermined manipulation. The manipulation may be, for example, a manipulation with which the manipulation body newly comes in contact with (e.g., taps or touches) the touch panel or a process in which the manipulation body moves (e.g., swipes or slides) on the touch panel.

For example, in a case in which the invalidation time is set and even when the manipulation determination unit 213 may determine that the manipulation body newly comes in contact with (e.g., taps or touches) the touch panel within the invalidation time, the process corresponding to the contact (e.g., tap or touch) is not executed. For example, in a case in which the invalidation time is set and the manipulation determination unit 213 determines that the manipulation body moves (swipes or slides) on the touch panel within the invalidation time, the process corresponding to the movement (swiping or sliding) may not be executed.

For example, when the elapsed time after the manipulation body stops on the touch panel is N seconds, the manipulation detector 212 may set the invalidation time to “N/10” seconds. For example, when the elapsed time after the manipulation body stopped on the touch panel is “0.1” second, the manipulation detector 212 may set the invalidation time to “0.1/10=0.01” second. It should be noted that the function set for the manipulation detector 212 to set the invalidation time is not limited, and any function may be used.

When the invalidation time and the invalidation range have been set, the manipulation determination unit 213 may not execute a process corresponding to the manipulation content notified from the manipulation determination unit 213 with respect to a predetermined manipulation within the invalidation range at the invalidation time. The predetermined manipulation may be, for example, a manipulation in which the manipulation body newly comes in contact with (e.g., taps or touches) the touch panel, or a process in which the manipulation body moves (e.g., swipes or slides) on the touch panel.

It should be noted that even when the invalidation time and the invalidation range are set, the manipulation determination unit 213 may execute a process corresponding to the manipulation at the stop position. For example, in a case in which the manipulation body is separated (released) from the touch panel at the stop position, the manipulation determination unit 213 may execute a process corresponding to the object (e.g., the icon) displayed at the stop position on the basis of the manipulation content indicating the separation (the release). Further, when the invalidation time and the invalidation range are set, the manipulation determination unit 213 may execute the process corresponding to the manipulation outside the invalidation range. For example, when the manipulation body is separated (released) from the touch panel outside the invalidation range, the manipulation determination unit 213 may execute the process corresponding to the object on the basis of the manipulation content indicating the separation (the release).

By the manipulation determination unit 213 setting the invalidation time and the invalidation range, the process corresponding to the manipulation content executed within the invalidation range may not be executed within the invalidation time. Therefore, it is possible to reduce or prevent an erroneous manipulation of the user.

As described above, by the manipulation determination unit 213 setting the invalidation time and the invalidation range, the process corresponding to the manipulation content executed within the invalidation range may not be executed within the invalidation time. Therefore, it is possible to reduce or prevent an erroneous manipulation of the user.

According to some example embodiments of the inventive concepts, when a manipulation body of a user (e.g., a finger or a stylus pen) makes a subsequent or ensuing manipulation on a user terminal after performing an first manipulation (e.g., a first movement) and stopping the first manipulation at a stop position on a terminal of the user, the user terminal may determine whether or not the subsequent or ensuing manipulation is made within a invalidation time and/or invalidation range, and may be configured to not perform a process corresponding a manipulation content associated with the subsequent or ensuing manipulation (e.g., may not affect a process corresponding a manipulation corresponding to the first manipulation) based on a determination result indicating that the subsequent or ensuing manipulation is within the invalidation time or the invalidation range. Therefore, it is possible to implement a user terminal that is capable of performing a first process corresponding to first manipulation content associated with a first manipulation (e.g., movement) of a user, while keeping a subsequent or ensuing manipulation of the user satisfying a certain criteria from affecting the first process.

Although the present inventive concepts have been described with reference to the drawings and some example embodiments, it should be noted that those skilled in the art can easily make various modifications or variations to the disclosed example embodiments. Therefore, it should be noted that these modifications or variations are included in the scope of the present disclosure. For example, the functions or the like included in each means, each step, or the like can be rearranged not to be logically contradictory, and it is possible to combine or divide a plurality of means, steps, or the like into one. Further, the configurations described in the above example embodiments may be appropriately combined.

What is claimed is:

1. An information processing method in an information processing terminal comprising:
detecting a manipulation with respect to a touch panel by a manipulation body that performs a manipulation input;
executing process content corresponding to the detected manipulation;
displaying display-content corresponding to the executed process content;
determining an invalidation time, the invalidation time being a time to invalidate the process content corresponding to the manipulation by the manipulation body, in response to an elapsed time after a movement of the manipulation body on the touch panel has stopped exceeding a threshold time; and
causing not to execute the executed process content based on a determination that the detected manipulation is within the invalidation time.

2. The information processing method according to claim 1, wherein
the detecting includes detecting a separation manipulation of separating the manipulation body from the touch panel within the invalidation time, and
the executing includes executing the process content corresponding to the separating manipulation based on a position at which the movement of the manipulation body is separated from the touch panel.

3. The information processing method according to claim 2, wherein the executing includes executing the process content corresponding to the separating manipulation with respect to an object displayed at a position at which the manipulation body is separated from the touch panel.

4. The information processing method according to claim 1, wherein the determining includes determining a length of the invalidation time based on an elapsed time after the movement of the manipulation body stops.

5. The information processing method according to claim 1, further comprising:
storing information on the process content corresponding to the detected manipulation based on a detection result that the detected manipulation with respect to the touch panel of the manipulation body is within the invalidation time.

6. The information processing method according to claim 5, wherein
the detecting further includes detecting a restarting movement of the manipulation body on the touch panel after the movement has stopped, and
the executing includes executing the process content corresponding to the detected manipulation, which is associated with the restarting movement, and the stored information in response to the restarting movement exceeding the invalidation time.

7. The information processing method according to claim 6, wherein the displaying includes displaying the display-content corresponding to the executed process content at the invalidation time in response to the restarting movement exceeding the invalidation time.

8. The information processing method according to claim 1, wherein
the determining further includes determining an invalidation range, the invalidation range being a range in which the process content corresponding to the detected manipulation by the manipulation body is invalidated on the touch panel, in response to the elapsed time after the movement of the manipulation body on the touch panel has stopped exceeding both the threshold time and the invalidation time, and
the causing includes causing not to execute the executed process content corresponding to the manipulation of the manipulation body that is within both the invalidation range and the invalidation time.

9. The information processing method according to claim 8, wherein the determining further includes determining the invalidation range based on a function.

10. The information processing method according to claim 1, wherein the determining further includes determining the invalidation time based on a function.

11. A non-transitory computer-readable recording medium storing a program that, when executed by a processor, causes the processor to execute an information processing method, the method comprising:
detecting a manipulation with respect to a touch panel by a manipulation body that performs a manipulation input;
executing process content corresponding to the detected manipulation;
displaying display-content corresponding to the executed process content;
determining an invalidation time, is the invalidation time being a time to invalidate the process content corresponding to the manipulation by the manipulation body based on an elapsed time after a movement of the manipulation body on the touch panel stops exceeds a threshold time; and
causing not to execute the process content based on a determination that the detected manipulation is within the invalidation time.

12. An information processing terminal comprising:
a storage configured to store computer-readable instructions; and
one or more processors configured to execute the computer-readable instructions such that the one or more processors are configured to,
detect a manipulation with respect to a touch panel by a manipulation body that performs a manipulation input,
execute process content corresponding to the detected manipulation,
display display-content corresponding to the executed process content,
determine an invalidation time, the invalidation time being a time to invalidate the process content corresponding to the manipulation of the manipulation body based on an elapsed time after a movement by the manipulation body on the touch panel stops exceeds a threshold time, and
cause not to execute the process content based on a determination that the detected manipulation is within the determined invalidation time.
